(19) United States
(12) Patent Application Publication
(10) Pub. No.: US 2023/0230933 A1
(43) Pub. Date: Jul. 20, 2023

(54) CHIP PACKAGE AND MANUFACTURING METHOD THEREOF

(71) Applicant: XINTEC INC., Taoyuan City (TW)

(72) Inventors: Chia-Ming CHENG, New Taipei City (TW); Chaung-Lin LAI, Taoyuan City (TW); Shu-Ming CHANG, New Taipei City (TW); Tsang-Yu LIU, Zhubei City (TW)

(21) Appl. No.: 18/149,029

(22) Filed: Dec. 30, 2022

Related U.S. Application Data
(60) Provisional application No. 63/299,704, filed on Jan. 14, 2022.

(51) Int. Cl. H01L 23/544; H01L 27/146

(52) U.S. Cl. CPC H01L 23/544; H01L 27/14618; H01L 27/14683; H01L 2223/54433

(57) ABSTRACT

A chip package includes a sensing element, a dam layer, and a light transmissive cover. A surface of the sensing element has a sensing area and a conductive pad. The conductive pad is adjacent to an edge of the surface of the sensing element. The dam layer is located on the surface of the sensing element and surrounds the sensing area. The dam layer has a main portion and plural mark portions. The mark portions are respectively located in plural corners of the main portion, located in a sidewall of the main portion, respectively located on plural corners of the sensing element, respectively located on plural inner edges of the main portion, or respectively located on plural outer edges of the main portion. The light transmissive cover is located on the dam layer.

### CROSS-REFERENCE TO RELATED APPLICATIONS

This application claims priority to U.S. Provisional Application Ser. No. 63/299,704, filed Jan. 14, 2022, which is herein incorporated by reference.

### BACKGROUND

### Field of Invention

The present disclosure relates to a chip package and a manufacturing method of the chip package.

### Description of Related Art

With the advancement of integrated circuit (IC) manufacturing technology, the size of the wafers is getting smaller and smaller, so it is not easy to track the wafers in the production process. Traditionally, additional manufacturing process may be used to create numbers on the wafers to facilitate tracking of the wafers during manufacture. However, additional manufacturing process increases the manufacturing cost and production time, thereby reducing the competitiveness of the product.

### SUMMARY

One aspect of the present disclosure provides a chip package.

According to some embodiments of the present disclosure, a chip package includes a sensing element, a dam layer, and a light transmissive cover. A surface of the sensing element has a sensing area and a conductive pad. The conductive pad is adjacent to an edge of the surface of the sensing element. The dam layer is located on the surface of the sensing element and surrounds the sensing area. The dam layer has a main portion and plural mark portions. The mark portions are respectively located in plural corners of the main portion, located in a sidewall of the main portion, respectively located on plural corners of the sensing element, respectively located on plural inner edges of the main portion, or respectively located on plural outer edges of the main portion. The light transmissive cover is located on the dam layer.

In some embodiments, the mark portions of the dam layer are binary patterns, octal patterns, decimal patterns, or hexadecimal patterns.

In some embodiments, the mark portions are respectively located in the corners of the main portion, the mark portions are separated from each other.

In some embodiments, the mark portions are openings through the dam layer.

In some embodiments, when the mark portions are located in the sidewall of the main portion, the mark portions are adjacent to each other.

In some embodiments, the mark portions are concave portions, and top surfaces of the concave portions are lower than a top surface of the main portion.

In some embodiments, when the mark portions are respectively located on the corners of the sensing element, the mark portions are separated from each other.

In some embodiments, the mark portions are convex portions, and the convex portions and the main portion include a same material.

In some embodiments, top surfaces of the mark portions are level with a top surface of the main portion.

In some embodiments, when the mark portions are respectively located on the inner edges of the main portion, the mark portions are separated from each other.

In some embodiments, each of the inner edges of the main portion is a zigzag shape, and a shape of each of the mark portions is different from the zigzag shape.

In some embodiments, the mark portions are concave portions, convex portions, or combinations thereof.

In some embodiments, when respectively located on the outer edges of the main portion, the mark portions are separated from each other.

In some embodiments, each of the outer edges of the main portion is a line shape, and a shape of each of the mark portions is different from the line shape.

In some embodiments, the mark portions are concave portions, convex portions, or combinations thereof.

Another aspect of the present disclosure provides a manufacturing method of a chip package.

According to some embodiments of the present disclosure, a manufacturing method of a chip package includes forming a dam layer on one of a light transmissive cover and a sensing element, wherein a surface of the sensing element has a sensing area and a conductive pad, and the conductive pad is adjacent to an edge of the surface; patterning the dam layer such that the dam layer has a main portion and a plurality of mark portions, wherein the mark portions are respectively located in a plurality of corners of the main portion, located in a sidewall of the main portion, respectively located on a plurality of corners of the sensing element, respectively located on a plurality of inner edges of the main portion, or respectively located on a plurality of outer edges of the main portion; and bonding the dam layer to the other one of the light transmissive cover and the sensing element.

In some embodiments, the manufacturing method of the chip package further includes cutting the light transmissive cover.

In the aforementioned embodiments of the present disclosure, since the mark portions of the dam layer may be respectively located in the corners of the main portion, located in the sidewall of the main portion, respectively located on the corners of the sensing element, respectively located on the inner edges of the main portion, or respectively located on the outer edges of the main portion, the chip package can be numbered based on the pattern combination of the mark portions, which facilitates tracking of the chip package during manufacture. Moreover, the mark portions and the main portion of the dam layer can be formed in the same patterning step, and thus additional process can be omitted to reduce the manufacturing cost and production time of the chip package, which facilitates the competitiveness of the product.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view of a chip package according to one embodiment of the present disclosure.

FIG. 2 is a partially enlarged view of a mark portion of a dam layer of FIG. 1.

FIGS. 3A to 3D are partially enlarged views of the mark portions of FIG. 1.

FIGS. 4 to 7 are cross-sectional views at various stages of a manufacturing method of the chip package of FIG. 1.

FIG. 8 is a top view of a chip package according to another embodiment of the present disclosure.

FIG. 9 is a partially enlarged view of the mark portions of the dam layer of FIG. 8.

FIGS. 10 to 12 are cross-sectional views at various stages of a manufacturing method of the chip package of FIG. 8.

FIG. 13 is a top view of a chip package according to yet another embodiment of the present disclosure.

FIG. 14 is a partially enlarged view of the mark portions of the dam layer of FIG. 13.

FIGS. 15 to 18 are cross-sectional views at various stages of a manufacturing method of the chip package of FIG. 13.

FIG. 19 is a top view of a chip package according to still another embodiment of the present disclosure.

FIG. 20 is a partially enlarged view of the mark portions of the dam layer of FIG. 19.

FIGS. 21 to 24 are cross-sectional views at various stages of a manufacturing method of the chip package of FIG. 19.

FIG. 25 is a top view of a chip package according to one embodiment of the present disclosure.

FIGS. 26A to 26D are partially enlarged views of the mark portions of FIG. 25.

FIG. 27 is a top view of a chip package according to another embodiment of the present disclosure.

FIGS. 28A to 28D are partially enlarged views of the mark portions of FIG. 27.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

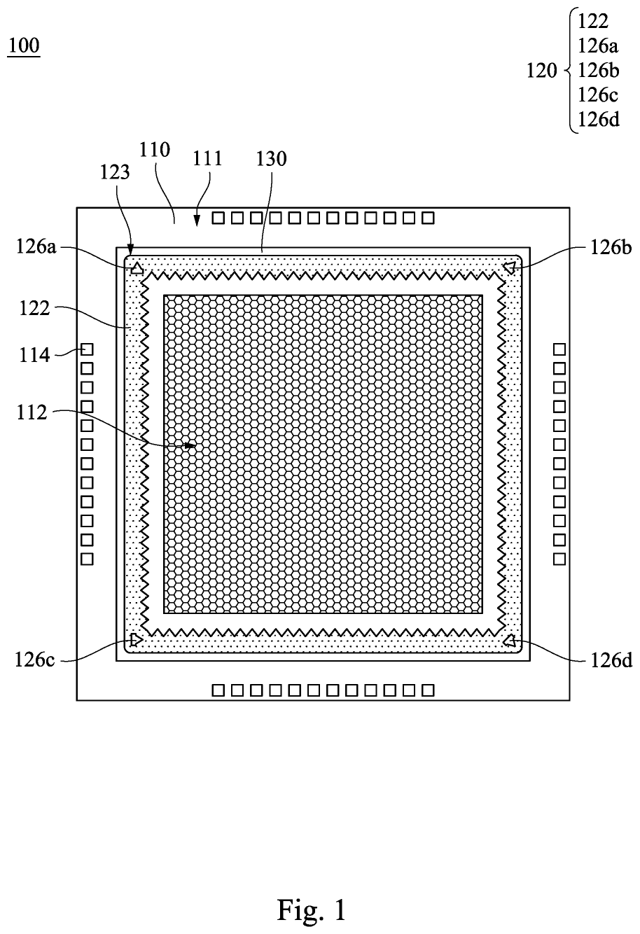

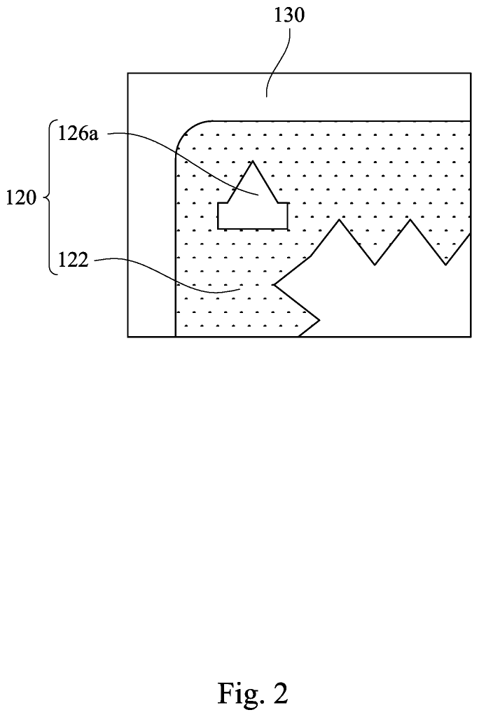

FIG. 1 is a top view of a chip package 100 according to one embodiment of the present disclosure. FIG. 2 is a partially enlarged view of a mark portion 126a of a dam layer 120 of FIG. 1. As shown in FIG. 1 and FIG. 2, the chip package 100 includes a sensing element 110, the dam layer 120, and a light transmissive cover 130. A surface 111 of the sensing element 110 has a sensing area 112 and a conductive pad 114. The conductive pad 114 is adjacent to an edge of the surface 111 of the sensing element 110. The dam layer 120 is located on the surface 111 of the sensing element 110 and surrounds the sensing area 112. The dam layer 120 has a main portion 122 and plural mark portions 126a, 126b, 126c, and 126d. In this embodiment, the number of the mark portions and the number of the corner 123 of the main portion 122 are four, but the present disclosure is not limited in this regard. The four mark portions 126a, 126b, 126c, and 126d are respectively located in the four corners 123 of the main portion 122. The mark portions 126a, 126b, 126c, and 126d of the dam layer 120 may be binary patterns, octal patterns, decimal patterns, or hexadecimal patterns, as deemed necessary by design. Furthermore, the light transmissive cover 130 is located on the dam layer 120, and the sensing area 112 may receive light passing through the light transmissive cover 130.

In addition, since the mark portions 126a, 126b, 126c, and 126d are respectively located in the corners 123 of the main portion 122, the mark portions 126a, 126b, 126c, and 126d are separated from each other. In this embodiment, the mark portions 126a, 126b, 126c, and 126d may be openings that are through the dam layer 120.

In this embodiment, the sensing element 110 may be an image sensing element, such as CIS (CMOS image sensor) sensing element. The material of the dam layer 120 may include epoxy, and the dam layer 120 is a photosensitive material. Moreover, the light transmissive cover 130 may be a glass sheet to enable light to pass through the light transmissive cover 130 to the sensing area 112.

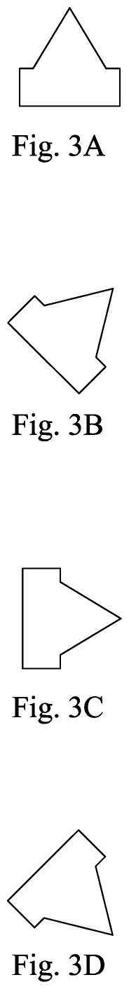

FIGS. 3A to 3D are partially enlarged views of the mark portions 126a, 126b, 126c, and 126d of FIG. 1. In FIG. 1, the pattern of the mark portion 126a may define an X value, the pattern of the mark portion 126b may define a x value, the pattern of the mark portion 126c may define a Y value, and the pattern of the mark portion 126d may define a y value, such that the chip package 100 has a number XxYy. In this embodiment, FIG. 3A may present the value 1, FIG. 3B may present the value 2, FIG. 3C may present the value 3, and FIG. 3D may present the value 4. After the dam layer 120 of the chip package 100 forms the mark portions 126a, 126b, 126c, and 126d, the number XxYy of the chip package 100 may be identified as 1234 by an apparatus.

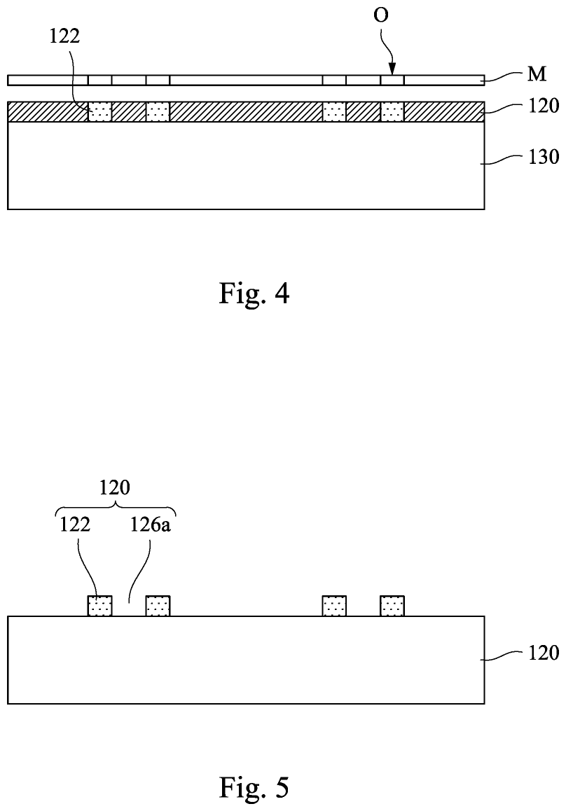

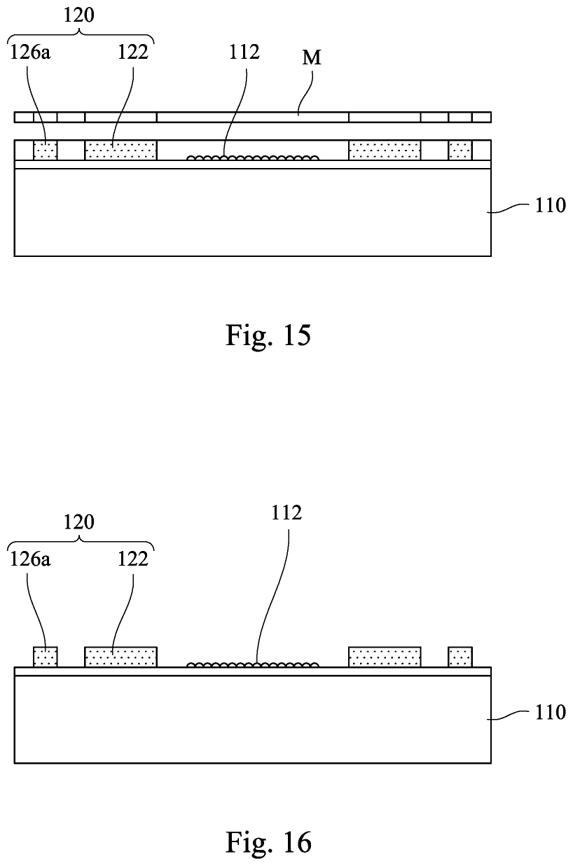

FIGS. 4 to 7 are cross-sectional views at various stages of a manufacturing method of the chip package 100 of FIG. 1. As shown in FIG. 4 and FIG. 5, the dam layer 120 is formed on the light transmissive cover 130, and then the dam layer 120 is patterned to have the main portion 122 and the mark portion 126a. It should be understood that the mark portion 126a is only an example. In fact, the mark portions 126b, 126c, and 126d are simultaneously formed during the formation of the mark portion 126a. In the aforementioned step, a photo (exposure) process may be performed on the dam layer 120 by using a mask M that has an opening O, such that the dam layer 120 defines the main portion 122 and the mark portion 126a. In alternative embodiments, the dam layer 120 may be formed on the sensing element 110 (will be described in FIG. 15). Thereafter, a development process may be performed to remove portions of the dam layer 120 that do not receive light, thereby forming the mark portion 126a with an opening type.

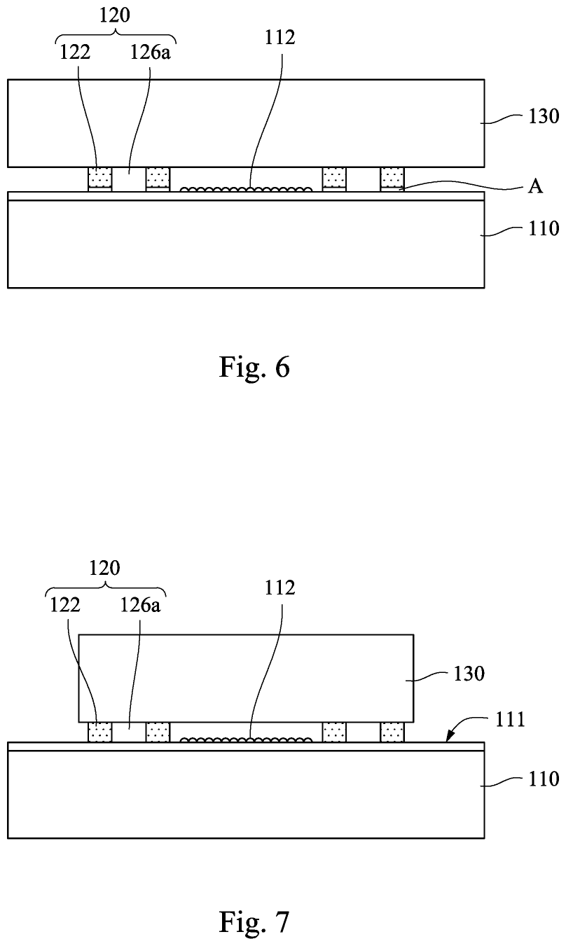

Referring to FIG. 6, after the dam layer 120 is patterned, the dam layer 120 may be bonded to the sensing element 110 by using an adhesive A, such that the dam layer 120 surrounds the sensing area 112. Referring to FIG. 7, thereafter, the light transmissive cover 130 may be cut, and thus the chip package 100 of FIG. 1 can be obtained.

As shown in FIG. 1, since the mark portions 126a, 126b, 126c, and 126d of the dam layer 120 may be respectively located in the corners 123 of the main portion 122, the chip package 100 can be numbered based on the pattern combination of the mark portions 126a, 126b, 126c, and 126d, which facilitates tracking of the chip package 100 during manufacture. Moreover, the mark portions 126a, 126b, 126c, and 126d and the main portion 122 of the dam layer 120 can be formed in the same patterning step, and thus additional process can be omitted to reduce the manufacturing cost and production time of the chip package 100, which facilitates the competitiveness of the product.

It is to be noted that the connection relationships, the materials, and the advantages of the elements described above will not be repeated in the following description. In the following description, other types of chip packages and the manufacturing methods of the chip packages will be explained.

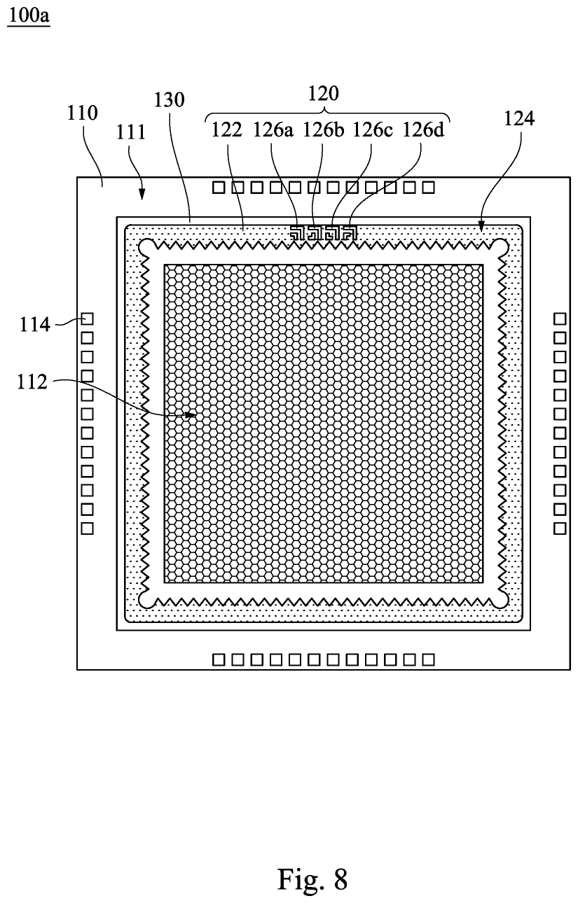

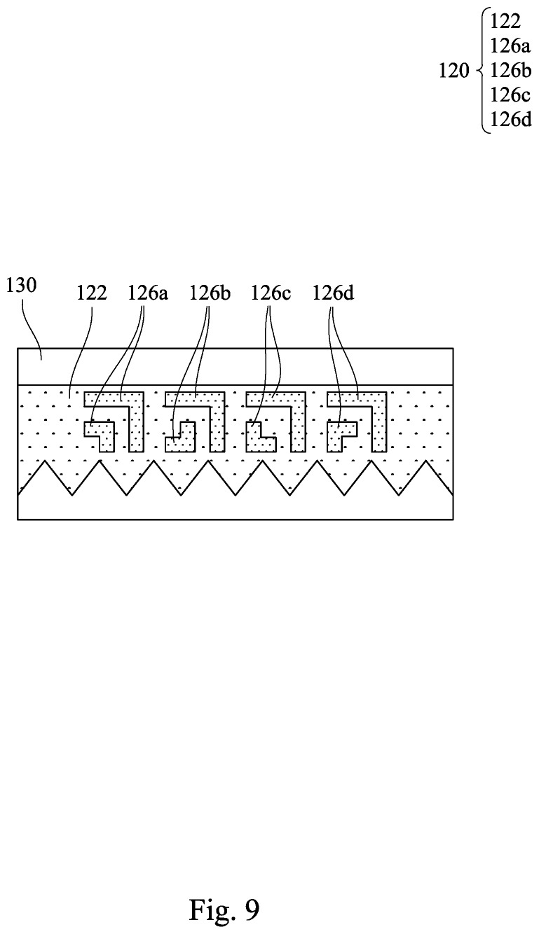

FIG. 8 is a top view of a chip package 100a according to another embodiment of the present disclosure. FIG. 9 is a partially enlarged view of the mark portions 126a, 126b, 126c, and 126d of the dam layer 120 of FIG. 8. As shown in FIG. 8 and FIG. 9, the chip package 100a includes the sensing element 110, the dam layer 120, and the light transmissive cover 130. The difference between this embodiment and the embodiment of FIG. 1 is that the mark portions 126a, 126b, 126c, and 126d of the dam layer 120 of the chip package 100a are located in a sidewall 124 of the main portion 122. For example, all the mark portions 126a, 126b, 126c, and 126d are located at one side (e.g., an upper side) of the main portion 122 and in the sidewall 124, and the mark portions 126a, 126b, 126c, and 126d are adjacent to each other. Furthermore, the mark portions 126a, 126b, 126c, and 126d may be concave portions, such as blind holes, and the top surfaces of the concave portions are lower than the top surface of the main portion 122.

The pattern of the mark portion 126a of the dam layer 120 may define an X value, the pattern of the mark portion 126b may define a x value, the pattern of the mark portion 126c may define a Y value, and the pattern of the mark portion 126d may define a y value, such that the chip package 100a has a number XxYy. In this embodiment, the mark portions 126a, 126b, 126c, and 126d of FIG. 9 may respectively present the values 1, 2, 3, and 4. After the dam layer 120 of the chip package 100a forms the mark portions 126a, 126b, 126c, and 126d, the number XxYy of the chip package 100a may be identified as 1234 by an apparatus.

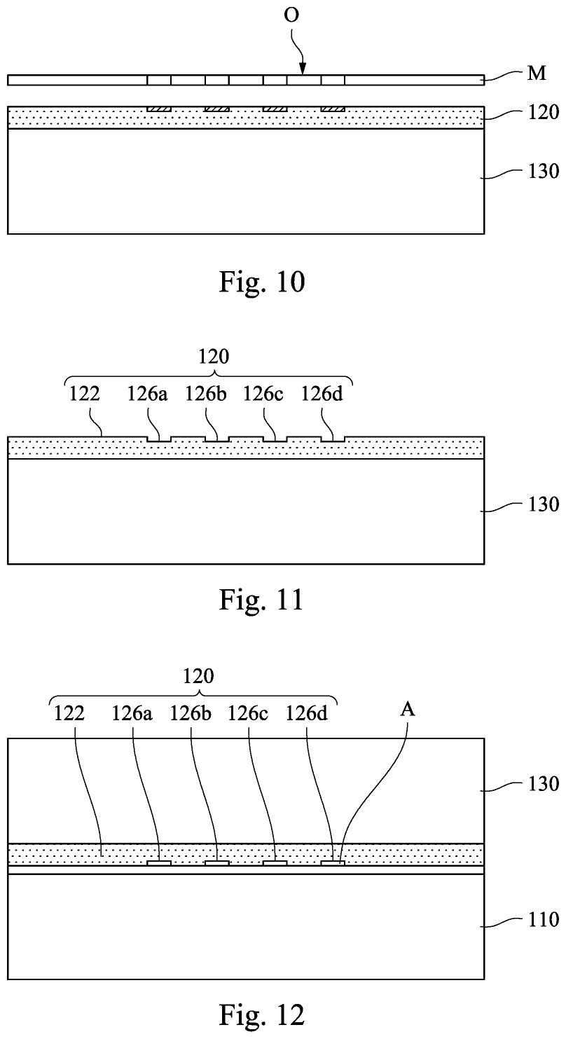

FIGS. 10 to 12 are cross-sectional views at various stages of a manufacturing method of the chip package 100a of FIG. 8. As shown in FIG. 10 and FIG. 11, the dam layer 120 is formed on the light transmissive cover 130, and then the dam layer 120 is patterned to have the main portion 122 and the mark portions 126a, 126b, 126c, and 126d. In the aforementioned step, a photo (exposure) process may be performed on the dam layer 120 by using the mask M that has the openings O, such that the dam layer 120 defines the main portion 122 and the mark portions 126a, 126b, 126c, and 126d. In this embodiment, non-open regions of the mask M may enable a small amount of light to pass through. Thereafter, a development process may be performed to remove portions of the dam layer 120 receiving the small amount of light. As a result, the mark portions 126a, 126b, 126c, and 126d as concave portions (e.g., blind holes) can be formed.

As shown in FIG. 12, after the dam layer 120 is patterned, the dam layer 120 may be bonded to the sensing element 110 by using the adhesive A. Thereafter, a cutting step may be performed on the light transmissive cover 130, and thus the chip package 100a of FIG. 8 can be obtained.

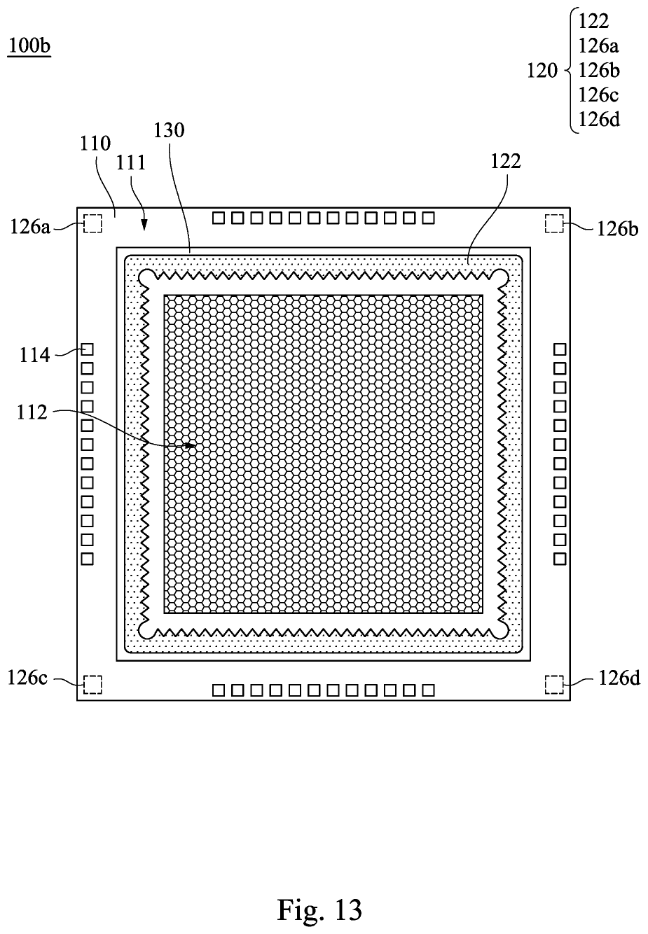

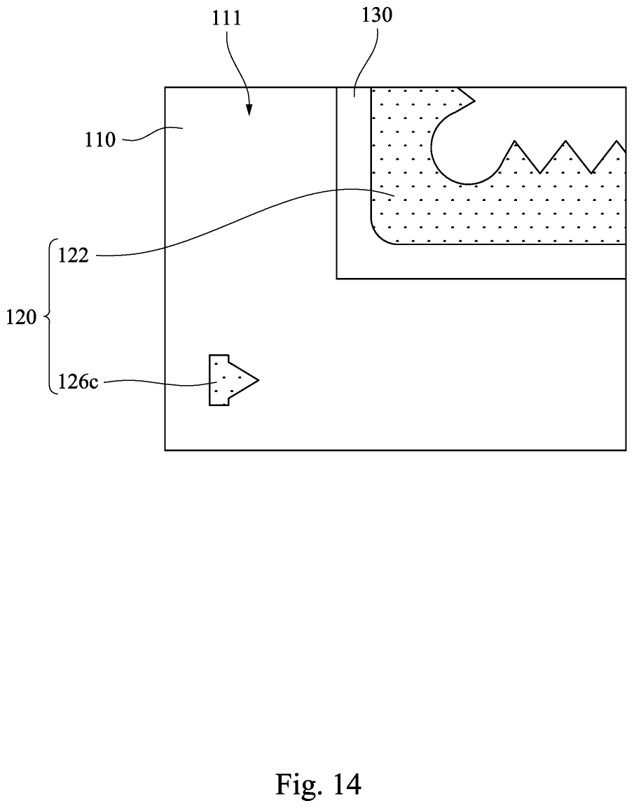

FIG. 13 is a top view of a chip package 100b according to yet another embodiment of the present disclosure. FIG. 14 is a partially enlarged view of the mark portions 126a, 126b, 126c, and 126d of the dam layer 120 of FIG. 13. As shown in FIG. 13 and FIG. 14, the chip package 100b includes the sensing element 110, the dam layer 120, and the light transmissive cover 130. The difference between this embodiment and the embodiment of FIG. 1 is that the mark portions 126a, 126b, 126c, and 126d of the dam layer 120 of the chip package 100b are respectively located on the four corners of the sensing element 110. In other words, the mark portions 126a, 126b, 126c, and 126d are located on the surface 111 of the sensing element 110, and the mark portions 126a, 126b, 126c, and 126d are separated from each other. Moreover, the mark portions 126a, 126b, 126c, and 126d may be convex portions, and the convex portions 126a, 126b, 126c, and 126d and the main portion 122 include the same material, and the top surfaces of the mark portions 126a, 126b, 126c, and 126d are level with the top surface of the main portion 122.

The pattern of the mark portion 126a of the dam layer 120 may define an X value, the pattern of the mark portion 126b may define a x value, the pattern of the mark portion 126c may define a Y value, and the pattern of the mark portion 126d may define a y value, such that the chip package 100b has a number XxYy. The pattern of each of the mark portions 126a, 126b, 126c, and 126d may be the pattern shown in one of FIGS. 3A to 3D. After the dam layer 120 of the chip package 100b forms the mark portions 126a, 126b, 126c, and 126d, the number

XxYy of the chip package 100b may be identified by an apparatus.

FIGS. 15 to 18 are cross-sectional views at various stages of a manufacturing method of the chip package 100b of FIG. 13. As shown in FIG. 15 and FIG. 16, the dam layer 120 is formed on the sensing element 110, and then the dam layer 120 is patterned to have the main portion 122 and the mark portion 126a. It should be understood that the mark portion 126a is only an example. In fact, the mark portions 126b, 126c, and 126d of FIG. 13 are simultaneously formed during the formation of the mark portion 126a. In the aforementioned step, a photo (exposure) process may be performed on the dam layer 120 by using the mask M that has the opening O, such that the dam layer 120 defines the main portion 122 and the mark portion 126a. Thereafter, a development process may be performed to remove portions of the dam layer 120 that do not receive light, thereby forming the mark portion 126a with a convex type. In addition, the main portion 122 of the dam layer 120 surrounds the sensing area 112.

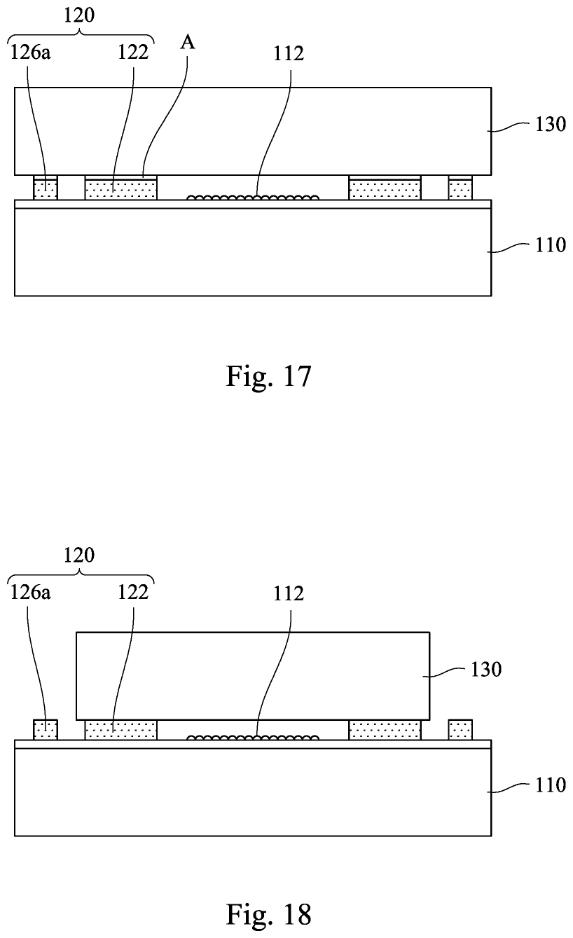

As shown in FIG. 17, after the dam layer 120 is patterned, the dam layer 120 may be bonded to the light transmissive cover 130 by using the adhesive A. Referring to FIG. 18, thereafter, the light transmissive cover 130 may be cut, and thus the chip package 100b of FIG. 13 can be obtained.

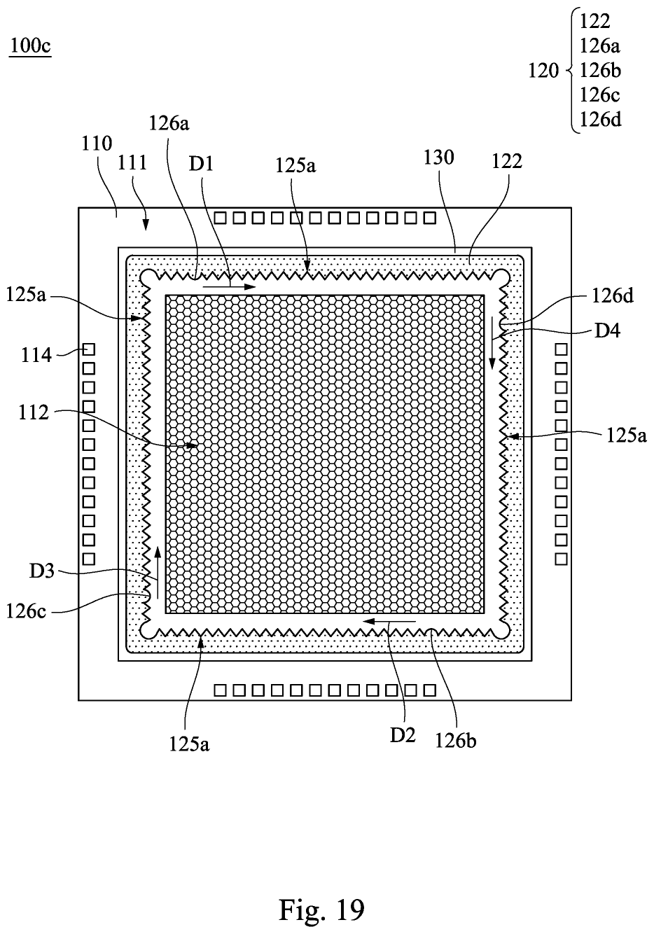

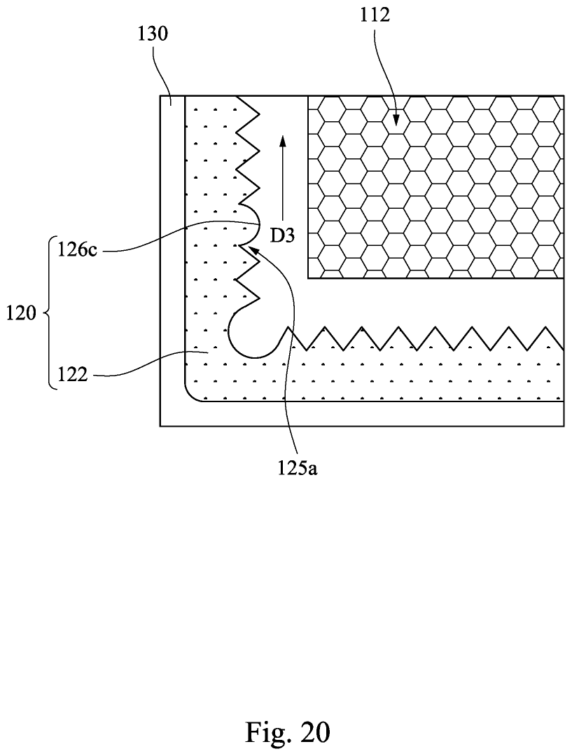

FIG. 19 is a top view of a chip package 100c according to still another embodiment of the present disclosure. FIG. 20 is a partially enlarged view of the mark portions 126a, 126b, 126c, and 126d of the dam layer 120 of FIG. 19. As shown in FIG. 19 and FIG. 20, the chip package 100c includes the sensing element 110, the dam layer 120, and the light transmissive cover 130. The difference between this embodiment and the embodiment of FIG. 1 is that the mark portions 126a, 126b, 126c, and 126d of the dam layer 120 of the chip package 100c are respectively located on four inner edges 125a of the main portion 122. The mark portions 126a, 126b, 126c, and 126d are separated from each other. Moreover, the inner edge 125a of the main portion 122 of the dam layer 120 is a zigzag shape, and a shape of each of the mark portions 126a, 126b, 126c, and 126d is different from the zigzag shape. For example, the mark portions 126a, 126b, 126c, and 126d may be concave portions, convex portions, or combinations thereof, and do not have zigzag shape (e.g., may have an arc shape, a trapezoid shape, and a rectangle shape).

In this embodiment, the mark portions 126a, 126b, 126c, and 126d are semicircular convex portions (as shown in FIG. 20) and have the same shape. The position of the mark portions 126a on the upper inner edges 125a replacing a tooth along a direction D1 may define a X value, the position of the mark portions 126b on the lower inner edges 125a replacing a tooth along a direction D2 may define a x value, the position of the mark portions 126c on the left inner edges 125a replacing a tooth along a direction D3 may define a Y value, and the position of the mark portions 126d on the right inner edges 125a replacing a tooth along a direction D4 may define a y value, such that the chip package 100c has a number XxYy. In this embodiment, the mark portions 126a, 126b, 126c, and 126d respectively replace the fourth tooth, the sixth tooth, the third tooth, and the fifth tooth, and may present the values 4, 6, 3, and 5. After the dam layer 120 of the chip package 100c forms the mark portions 126a, 126b, 126c, and 126d, the number XxYy of the chip package 100c may be identified as 4635 by an apparatus.

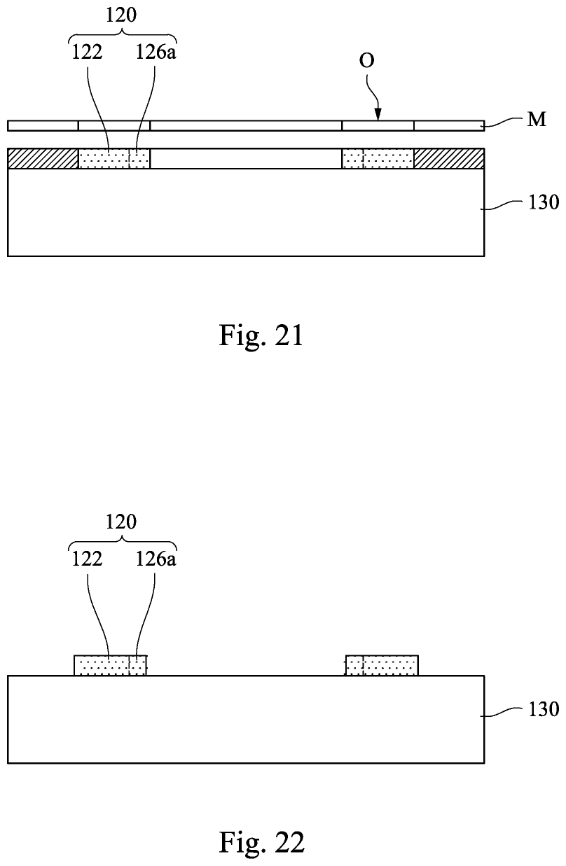

FIGS. 21 to 24 are cross-sectional views at various stages of a manufacturing method of the chip package 100c of FIG. 19. As shown in FIG. 21 and FIG. 22, the dam layer 120 is formed on the light transmissive cover 130, and then the dam layer 120 is patterned to have the main portion 122 and the mark portion 126a. It should be understood that the mark portion 126a is only an example. In fact, the mark portions 126b, 126c, and 126d of FIG. 19 are simultaneously formed during the formation of the mark portion 126a. In the aforementioned step, a photo (exposure) process may be performed on the dam layer 120 by using the mask M that has the opening O, such that the dam layer 120 defines the main portion 122 and the mark portion 126a. Thereafter, a development process may be performed to remove portions of the dam layer 120 that do not receive light, thereby forming the mark portion 126a that does not have a zigzag shape.

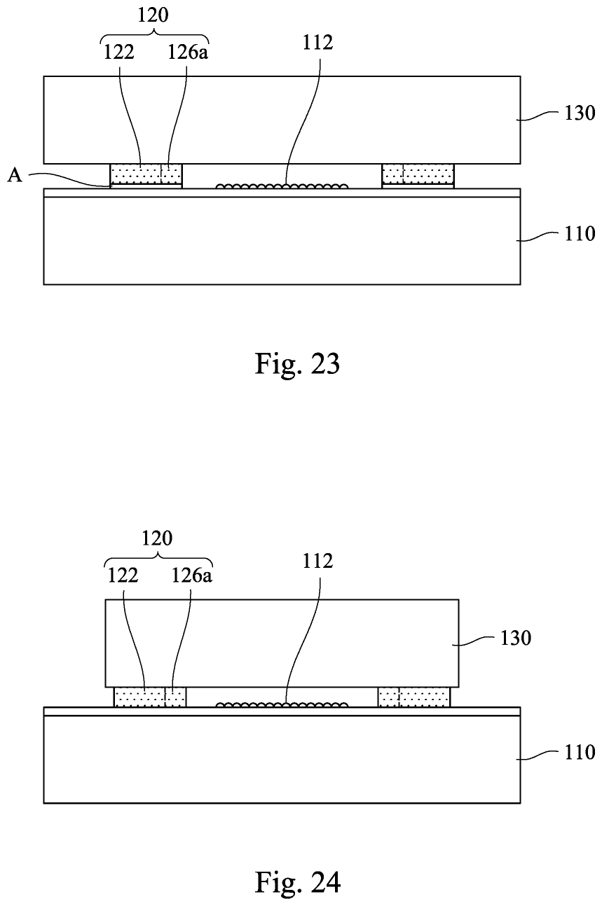

As shown in FIG. 23, after the dam layer 120 is patterned, the dam layer 120 may be bonded to the sensing element 110 by using the adhesive A, such that the dam layer 120 surrounds the sensing area 112. Referring to FIG. 24, thereafter, a cutting step may be performed on the light transmissive cover 130, and thus the chip package 100c of FIG. 19 can be obtained.

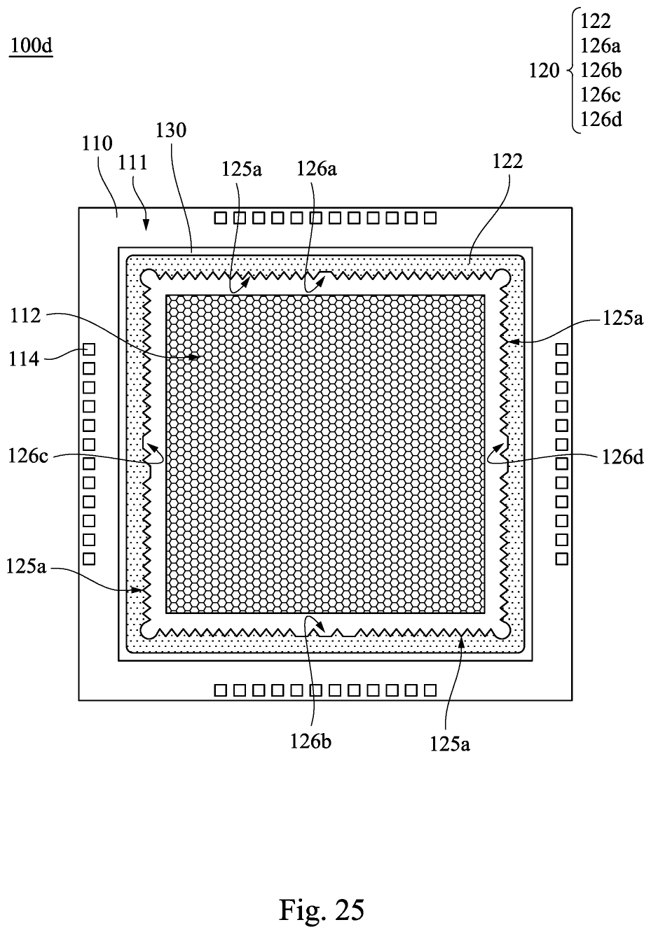

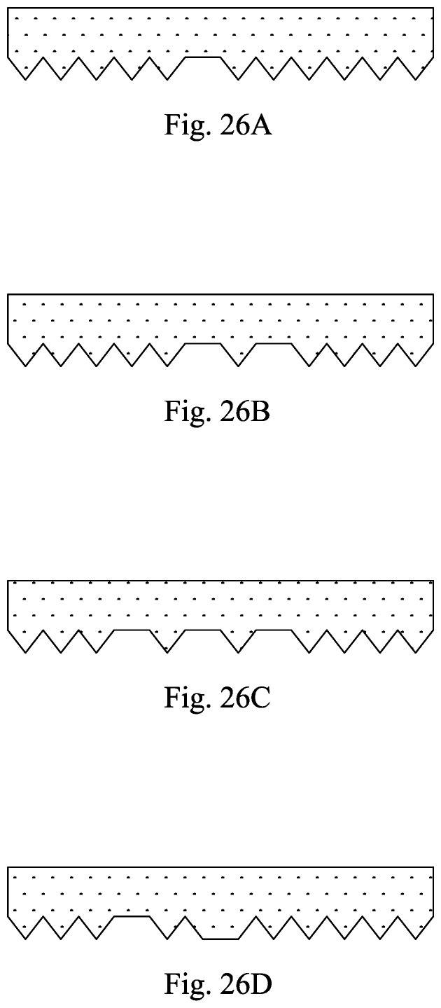

FIG. 25 is a top view of a chip package 100d according to one embodiment of the present disclosure. FIGS. 26A to 26D are partially enlarged views of the mark portions 126a, 126b, 126c, and 126d of FIG. 25. The chip package 100d includes the sensing element 110, the dam layer 120, and the light transmissive cover 130. The difference between this embodiment and the embodiment of FIG. 19 is that the pattern of the mark portion 126a of the dam layer 120 of the chip package 100d may define an X value, the pattern of the mark portion 126b may define a x value, the pattern of the mark portion 126c may define a Y value, and the pattern of the mark portion 126d may define a y value, such that the chip package 100d has a number XxYy. In this embodiment, FIG. 26A may present the value 1, FIG. 26B may present the value 2, FIG. 26C may present the value 3, and FIG. 26D may present the value 4. After the dam layer 120 of the chip package 100d forms the mark portions 126a, 126b, 126c, and 126d, the number XxYy of the chip package 100d may be identified as 1342 by an apparatus.

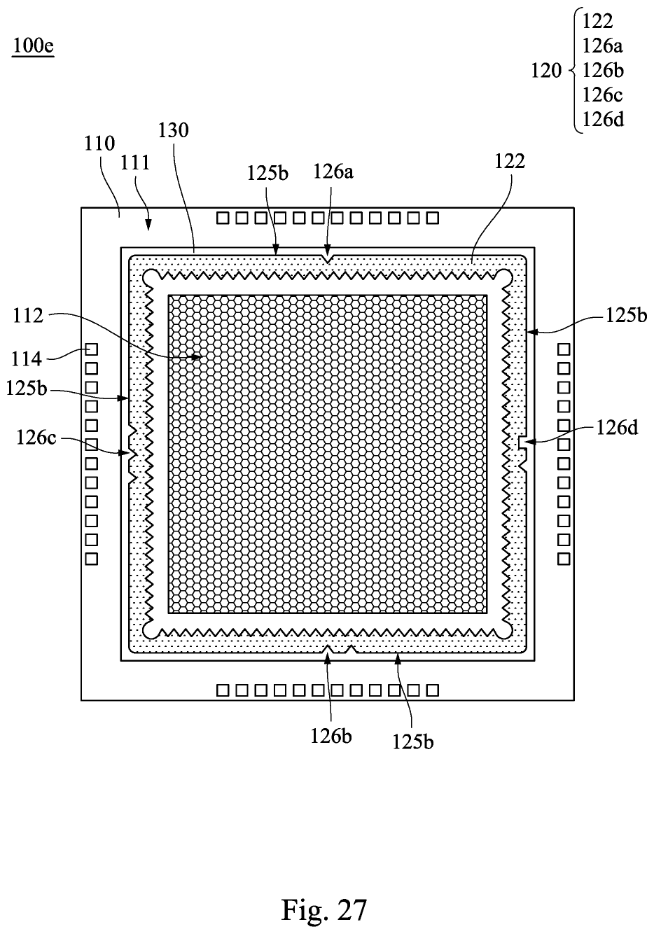

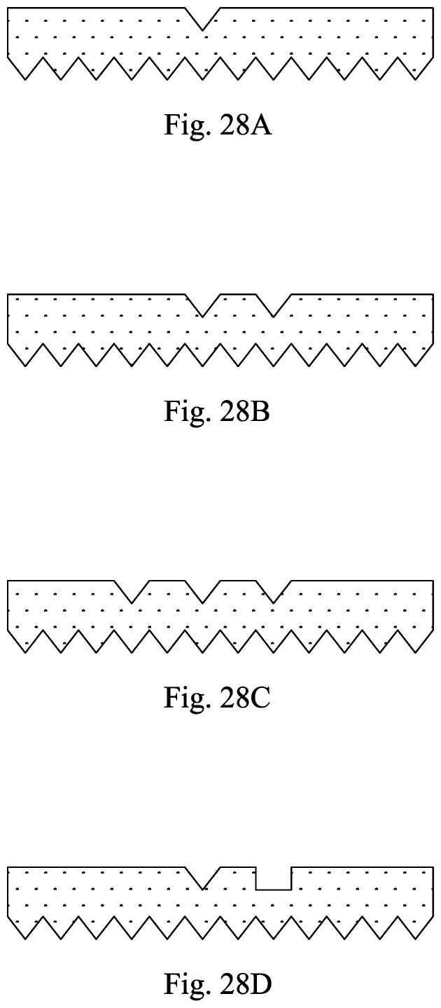

FIG. 27 is a top view of a chip package 100e according to another embodiment of the present disclosure. FIGS. 28A to 28D are partially enlarged views of the mark portions 126a, 126b, 126c, and 126d of FIG. 27. The chip package 100e includes the sensing element 110, the dam layer 120, and the light transmissive cover 130. The difference between this embodiment and the embodiment of FIG. 25 is that the mark portions 126a, 126b, 126c, and 126d of the dam layer 120 of the chip package 100e are respectively located on four outer edges 125b of the main portion 122. The mark portions 126a, 126b, 126c, and 126d are separated from each other. Moreover, the outer edge 125b of the main portion 122 of the dam layer 120 is a line shape, and a shape of each of the mark portions 126a, 126b, 126c, and 126d is different from the line shape. For example, the mark portions 126a, 126b, 126c, and 126d may be concave portions, convex portions, or combinations thereof, and do not have line shape (e.g., may have a triangular shape, an arc shape, a trapezoid shape, and a rectangle shape).

The pattern of the mark portion 126a of the dam layer 120 of the chip package 100e may define an X value, the pattern of the mark portion 126b may define a x value, the pattern of the mark portion 126c may define a Y value, and the pattern of the mark portion 126d may define a y value, such that the chip package 100d has a number XxYy. In this embodiment, FIG. 28A may present the value 1, FIG. 28B may present the value 2, FIG. 28C may present the value 3, and FIG. 28D may present the value 4. After the dam layer 120 of the chip package 100e forms the mark portions 126a, 126b, 126c, and 126d, the number XxYy of the chip package 100e may be identified as 1234 by an apparatus.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
a sensing element, wherein a surface of the sensing element has a sensing area and a conductive pad, and the conductive pad is adjacent to an edge of the surface;
a dam layer located on the surface of the sensing element and surrounds the sensing area, wherein the dam layer has a main portion and a plurality of mark portions, and the mark portions are respectively located in a plurality of corners of the main portion, located in a sidewall of the main portion, respectively located on a plurality of corners of the sensing element, respectively located on a plurality of inner edges of the main portion, or respectively located on a plurality of outer edges of the main portion; and
a light transmissive cover located on the dam layer.

2. The chip package of claim 1, wherein the mark portions of the dam layer are binary patterns, octal patterns, decimal patterns, or hexadecimal patterns.

3. The chip package of claim 1, wherein when the mark portions are respectively located in the corners of the main portion, the mark portions are separated from each other.

4. The chip package of claim 3, wherein the mark portions are openings through the dam layer.

5. The chip package of claim 1, wherein when the mark portions are located in the sidewall of the main portion, the mark portions are adjacent to each other.

6. The chip package of claim 5, wherein the mark portions are concave portions, and top surfaces of the concave portions are lower than a top surface of the main portion.

7. The chip package of claim 1, wherein when the mark portions are respectively located on the corners of the sensing element, the mark portions are separated from each other.

8. The chip package of claim 7, wherein the mark portions are convex portions, and the convex portions and the main portion comprise a same material.

9. The chip package of claim 7, wherein top surfaces of the mark portions are level with a top surface of the main portion.

10. The chip package of claim 1, wherein when the mark portions are respectively located on the inner edges of the main portion, the mark portions are separated from each other.

11. The chip package of claim 10, wherein each of the inner edges of the main portion is a zigzag shape, and a shape of each of the mark portions is different from the zigzag shape.

12. The chip package of claim 10, wherein the mark portions are concave portions, convex portions, or combinations thereof.

13. The chip package of claim 1, wherein when respectively located on the outer edges of the main portion, the mark portions are separated from each other.

14. The chip package of claim 13, wherein each of the outer edges of the main portion is a line shape, and a shape of each of the mark portions is different from the line shape.

15. The chip package of claim 13, wherein the mark portions are concave portions, convex portions, or combinations thereof.

16. A manufacturing method of a chip package, comprising:
forming a dam layer on one of a light transmissive cover and a sensing element, wherein a surface of the sensing element has a sensing area and a conductive pad, and the conductive pad is adjacent to an edge of the surface;
patterning the dam layer such that the dam layer has a main portion and a plurality of mark portions, wherein the mark portions are respectively located in a plurality of corners of the main portion, located in a sidewall of the main portion, respectively located on a plurality of corners of the sensing element, respectively located on a plurality of inner edges of the main portion, or respectively located on a plurality of outer edges of the main portion; and
bonding the dam layer to the other one of the light transmissive cover and the sensing element.

17. The manufacturing method of the chip package of claim 16, further comprising:
cutting the light transmissive cover.
